(19) United States
(12) Patent Application Publication
(10) Pub. No.: US 2025/0132532 A1
(43) Pub. Date: Apr. 24, 2025

(54) CONTACT DEVICE AND POWER MODULE ARRANGEMENT

(71) Applicant: Robert Bosch GmbH, Stuttgart (DE)

(72) Inventor: Irfan Aydogmus, Nuertingen (DE)

(21) Appl. No.: 18/915,544

(22) Filed: Oct. 15, 2024

(30) Foreign Application Priority Data
Oct. 20, 2023 (DE) 10 2023 210 385.0

(51) Int. Cl. H01R 25/16; H02M 7/00

(52) U.S. Cl. CPC H01R 25/162; H02M 7/003

(57) ABSTRACT

A contact device. The contact device includes at least a first and a second busbar, which are arranged at a distance from one another in an electrically insulated manner. Each busbar includes at least a first and a second contact region, each of which has at least one contact element. The contact device is configured such that, when the functional elements are electrically contacted with, in each case, two busbars on contact elements of different contact regions in switching operation, a current path is formed in each case between the first and the second contact region within the two busbars. The electrical contacting of the contact element of at least one contact region with at least one contact surface of a functional element can be formed in the form of a force-loaded galvanic system contact.

### FIELD

The present invention relates to a contact device and a power module arrangement with at least one power module and with at least one contact device electrically contacted with the power module in a connection interface, in particular for providing a phase current for an electrical machine.

### BACKGROUND INFORMATION

The related art describes power module arrangements in which a first connection interface between the at least one power module and a capacitor assembly comprising at least one capacitor, or a second connection interface between the at least one power module and a phase connection to an electrical machine are realized via welded connections.

For producing these welded connections, cost-intensive laser welding processes with corresponding laser welding devices are generally used. For a corresponding laser welding head, very large clearances are required in the power module arrangement. In addition, the laser welding process also produces conductive particles, which can later lead to short circuits in the installed power module arrangement.

### SUMMARY

An object of the present invention is to provide a cost-effective and technically easily realizable electrical contacting of at least two electrical functional components of an electrical and/or electronic circuit and/or subcircuit within at least one connection interface.

This object may be achieved by a contact device and a power module arrangement with at least one power module and with at least one contact device electrically contacted with the power module in a connection interface, in particular for providing a phase current for an electrical machine, having certain features of the present invention.

The present invention is based on a contact device for electrically contacting at least two electrical functional components of an electrical and/or electronic circuit and/or subcircuit within at least one connection interface. The two functional components to be electrically contacted are, for example, a power module and a capacitor as part of a commutation circuit for controlling an electric motor. According to an example embodiment of the present invention, the contact device comprises at least a first and a second busbar, which are arranged at a distance from one another in an electrically insulated manner. Each busbar comprises at least a first and a second contact region, each of which has at least one contact element. The contact device is designed in such a way that, when the functional elements are electrically contacted with, in each case, two busbars on contact elements of different contact regions in switching operation, a current path is formed in each case between the first and the second contact region within the two busbars. The electrical contacting of the contact element of at least one contact region with at least one contact surface of a functional element can be formed in the form of a force-loaded galvanic system contact in that the contact device has means which, in the contacting state of the contact device with at least one of the functional elements, effect a pressure force perpendicular to the contact surface as a contact force on the at least one contact element in the at least one contact region. The galvanic system contact therefore results solely from a force-loaded mechanical pressing (and holding) together of contact surfaces of the contact partners that otherwise lie loosely on one another. The busbars are each made of a plate-shaped base material with a plate thickness between two opposite outer surfaces. The busbars are thus preferably made of a sheet metal material as the plate material, more preferably of copper or a copper alloy. In this way, the first and the second busbar can advantageously each be designed as stamped and bent parts, which makes cost-effective mass production possible. The two busbars each have rail portions arranged in parallel with one another over an extension between the first and the second contact region. Furthermore, part or all of the rail portion of one busbar in each case has at least one laterally formed flange outlet, forming a side rail portion. The formed side rail portion is arranged in a different plane than the rail portion of the corresponding busbar. The side rail portions of the first and second busbars are arranged in parallel with one another, substantially overlapping one another. An overlap is visible in a perpendicular view of at least one of the side rail portions that are arranged in parallel with one another. When the contact device is operated in current mode with a current flowing through the two busbars, the additional side rail portions result in a very low-inductance overall behavior of the contact device. In particular, inductances that occur when the two busbars are at different potentials compensate one another. This works the better, the greater the surface area of the busbars facing one another is. The arrangement of rail portions and side rail portions in different planes also increases the structural rigidity so that the contact device is more loadable for differently oriented mechanical force effects.

Advantageous developments and improvements of the contact device according to the present invention are made possible by the measures disclosed herein.

In a further advantageous example embodiment of the contact device of the present invention, the side rail portion of one busbar in each case is formed on the rail portion over at least a partial portion, preferably over the entire rail portion, by means of at least one bend. The longer the partial portion is selected to be, the more a low inductance of the contact device can be positively influenced. Furthermore, this also results in an increased structural rigidity of the busbar.

Great advantages result from an example embodiment of the contact device of the present invention in which the rail portion and the side rail portion of one busbar in each case are arranged in parallel with one another or at an opening angle to one another via two bends, in each case as legs of a then U-shaped cross section of the busbar. The U-shaped cross-sectional design results in an optimally compact design while remaining rigid against mechanical force effects from different spatial directions. Arranging the legs at an opening angle to one another means that, in a substrate connecting them, the legs move further and further apart in a V-shape as one moves further along the leg portion.

There are various ways to arrange the first and the second busbar in relation to each other, in particular in a space-saving manner. In a preferred arrangement, the U-shaped cross sections of the first and the second busbar are arranged 180° in opposite directions to one another, wherein at least one leg of one of the busbars then engages between two legs of the other busbar. In an alternative arrangement, the U-shaped cross sections of the first and the second busbar are arranged in the same direction to one another, wherein the two legs of one of the busbars are then at a greater distance from each other than the two legs of the other busbar. Furthermore, the U-shaped cross section of the other busbar is then accommodated between the further protruding legs of the one busbar.

A particularly low inductance is exhibited by an example embodiment of the contact device of the present invention in which the rail portions and the side rail portions of both busbars are arranged in parallel with one another, substantially overlapping one another. Due to a high level of overlap, the current-related inductances within the two busbars act particularly strongly in opposite directions to one another.

In a preferred example embodiment of the contact device of the present invention, one busbar in each case has a continuous surface region over an extension from its first to its second contact region, in which contact region the normal vector of each surface point is oriented perpendicularly to a force vector of the pressure force. Such a defined specification allows a particularly high bending stiffness of the busbars to be used with an overall very compact design of the contact device. This means that high pressure forces can be provided or formed as contact forces for electrical contacting, without mechanically overloading the contact device. In addition, by making high pressure forces possible as contact forces, electrical contacting can be ensured by means of the contact device with low electrical resistance and a long service life.

In an advantageous example embodiment of the contact device of the present invention, at least the first and the second busbar are embedded in a common, electrically insulating sheathing, wherein the at least one contact element of the at least one first contact region and the at least one contact element of the at least one second contact region of one busbar in each case protrude from the sheathing. The sheathing advantageously forms a contact protection for the contact device so that there is no immediate danger to people or the environment when the contact device is used in operation, even at high electrical currents and/or voltages and when used as intended. The sheathing compound can be provided, for example, by a casting compound, for example made of a ceramic, or by an in particular polymeric injection-molding compound, for example a molding compound.

In a further development of the contact device of the present invention, the means for effecting the contact force comprise at least one elastic pressure element, which is designed to be prestressed by a mechanical force application in order to effect the contact force. By applying a force in the elastic region of the pressure element, a contact force can be set within a defined force value range or with a defined force value. Thus, a galvanic system contact to be formed can be designed to be electrically and mechanically safe over a specified service life, taking into account the material properties of the contact surface of the functional element to be electrically contacted. Preferably, the at least one elastic pressure element can be introduced into a recess of the electrically insulating sheathing so that it is protected against mechanical damage. The mechanical force application is then carried out in particular by means of a screw or nut, which acts on and prestresses the at least one elastic pressure element, forming the contact force. The elastic pressure element is designed in particular as a pressure disk made of spring steel. This makes a particularly cost-effective implementation of the elastic pressure element possible. Of course, the at least one elastic pressure element can also have another suitable design in order to effect the desired contact force, for example in the form of a clamping bracket or something else.

In a particularly favorable example embodiment of the contact device of the present invention, the at least one contact element of the at least one first contact region and/or the at least one contact element of the at least one second contact region are each designed as a row of sharp teeth. Furthermore, they are designed in such a way that they can be pressed into the at least one contact surface of the functional element by means of the contact force that can be effected in the form of a pressure force, forming the galvanic system contact. This makes a good electrical connection with low contact resistance and high current carrying capacity possible.

The present invention also leads to a power module arrangement with at least one power module, which comprises a plurality of semiconductor switches and at least one external contact surface. Furthermore, the power module arrangement also has at least one connection interface, which comprises at least one contact device in at least one of the above-described embodiments and at least one elastic pressure element. The elastic pressure element is prestressed by a mechanical force application, whereby a contact force is effected in the form of a pressure force, with which at least one contact element of the first contact region of at least one of the busbars is pressed against the at least one external contact surface, forming a galvanic system contact. The at least one connection interface makes a low-inductance and rigid electrical or mechanical connection between the at least one power module and an external supply connection and/or an external load connection possible via a simple mechanical force application. The mechanical force application is carried out, for example, by means of a screw connection. Such a connection interface with a simple mechanical force application can save installation space in the power module arrangement. In addition, such mechanical force applications can be produced more cost-effectively and easily than, for example, laser-welded connections.

In a further advantageous example embodiment of the power module arrangement of the present invention, a first connection interface comprises a first contact device and is designed to electrically connect at least a first external contact surface of the at least one power module to a first supply connection and to electrically connect at least a second external contact surface of the at least one power module to a second supply connection. The first connection interface allows the corresponding power module to be electrically connected in a single work step to the supply connections, which are, for example, provided by a capacitor assembly. Preferably, the busbars of the first contact devices can be arranged in parallel with one another at a certain distance from one another. Since the current directions in the two busbars are opposite to each other, the resulting parasitic magnetic fields can largely or at least partially cancel one another out so that a low-inductance connection with high current carrying capacity can be implemented between the corresponding power module and the supply connections. A second connection interface can comprise a further external contact device surrounded by an electrically insulating sheathing compound and can be designed to electrically connect at least a third external contact surface of the at least one power module to a load connection. Through the second connection interface, the corresponding power module can, for example, be electrically connected to a phase connection of an electrical machine. The sheathing, which is preferably formed by a hardened molding compound, can simplify the handling of the connection interfaces and ensure the position of the busbars over the service life of the power module arrangement. In addition, the sheathing protects the busbars from external influences.

In a further advantageous embodiment of the power module arrangement of the present invention, the at least one power module can be overmolded by a sheathing which can have an opening in the region of the at least one external contact surface so that the at least one external contact surface can be contacted. In the region of the at least one external contact element, an exposure can be introduced into the sheathing, for example by means of a laser, so that the at least one contact element is exposed and can be contacted.

In a further advantageous embodiment of the present invention, the power module arrangement can comprise three power modules. In this case, the at least one third external contact surface of a first power module can be electrically connected to a load connection designed as a first phase connection and can provide a first phase current for an electrical machine. The at least one third external contact surface of a second power module can be electrically connected to a load connection designed as a second phase connection and can provide a second phase current for the electrical machine. The at least one third external contact surface of a third power module can be electrically connected to a load connection designed as a third phase connection and can provide a third phase current for the electrical machine. In addition, the three power modules can each have a first connection interface, which electrically connects the corresponding power module to the first supply connection and the second supply connection, and can each have a second connection interface, which electrically connects the corresponding power module to the corresponding load connection. The power module arrangement with the three power modules can preferably be used as a power output stage for a three-phase electric motor.

One exemplary embodiment of the present invention is illustrated in the drawings and explained in more detail in the following description. In the figures, identical reference signs denote components or elements which perform the same or analogous functions.

### BRIEF DESCRIPTION OF THE DRAWINGS

Further advantages, features and details of the present invention can be found in the following description of preferred exemplary embodiments and with reference to the figures.

FIG. 1 is a schematic plan view of an exemplary embodiment of a power module arrangement according to the present invention.

FIG. 2 is a schematic plan view of an exemplary embodiment of a power module for the power module arrangement of FIG. 1, according to the present invention.

FIG. 3 is a schematic sectional view of the power module arrangement of FIG. 1, according to an example embodiment of the present invention.

FIG. 4A is a schematic perspective view of an exemplary embodiment of a contact device within the power module arrangement of FIG. 1 in an exploded view.

FIG. 4B shows the two busbars within the contact device of FIG. 4A in a schematic perspective view.

FIG. 4C shows a further embodiment of a contact device based on the second exemplary embodiment of FIG. 4A.

### DETAILED DESCRIPTION OF EXAMPLE EMBODIMENTS

In the figures, functionally identical components are each denoted by the same reference signs.

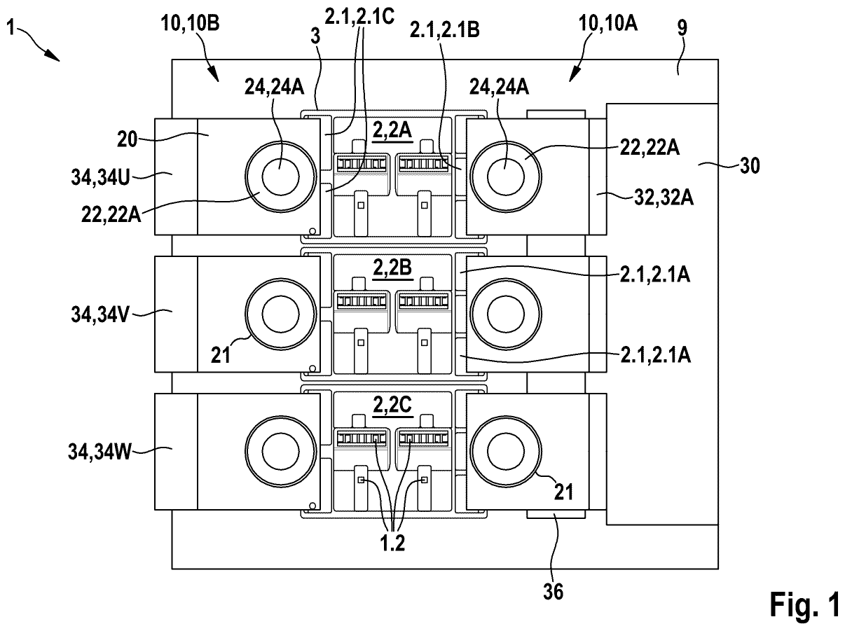

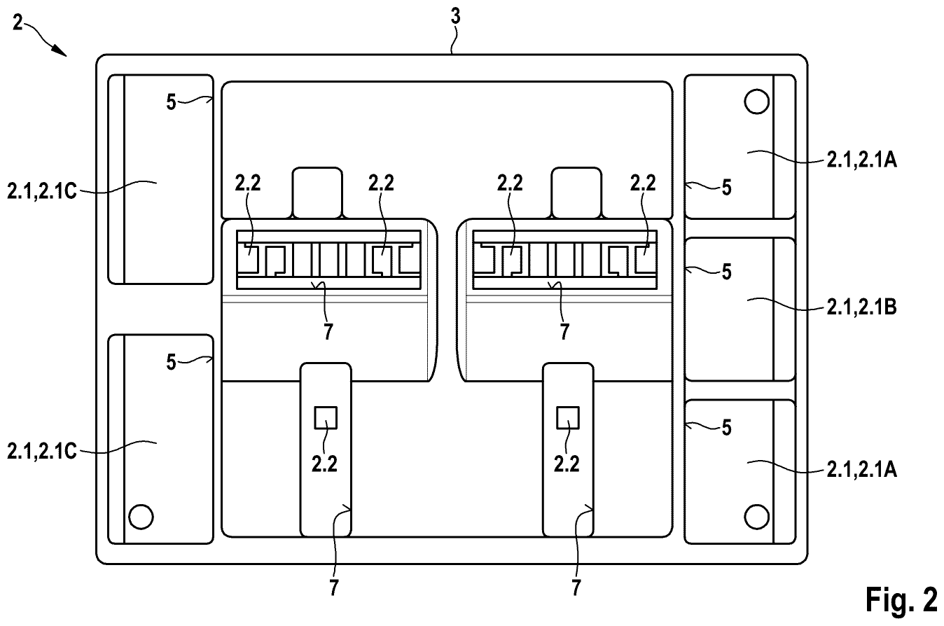

As can be seen in FIG. 1 to 4C, the illustrated exemplary embodiment of a power module arrangement 1 according to the present invention comprises at least one power module 2, 2A, 2B, 2C, which comprises a plurality of semiconductor switches (not shown in more detail) and at least one external contact surface 2.1, 2.1A, 2.1B, 2.1C, and at least one connection interface 10, 10A, 10B, which comprises at least one contact device 12, 12A, 12B and at least one elastic pressure element 22. The at least one connection interface 10, 10A, 10B electrically connects the at least one external contact surface 2.1, 2.1A, 2.1B, 2.1C of the power module 1 to at least one external supply connection 32 or to at least one external load connection 34. The at least one external contact device 12, 12A, 12B comprises at least two busbars 14, 14A, 14B, each with at least one first contact region 16, which contacts the at least one external contact surface 2.1, 2.1A, 2.1B, 2.1C with at least one contact element 16.1, and with at least one second contact region 18, which contacts the at least one external supply connection 32 or the at least one external load connection 34 with at least one contact element 18.1. The at least one contact device 12, 12A, 12B is overmolded by a sheathing 20 such that the at least one contact element 16.1 of the at least one first contact region 16 and the at least one contact element 18.1 of the at least one second contact region 18 protrude from the sheathing 20. In this case, a mechanical force application 24 acts on and prestresses the at least one elastic pressure element 22 in order to effect a contact force K in the form of a pressure force D, which presses the at least one contact element 16.1 of the at least one first contact region 16 against the at least one external contact surface 2.1, 2.1A, 2.1B, 2.1C and the at least one contact element 18.1 of the at least one second contact region 18 against the at least one external supply connection 32 or the at least one external load connection 34, forming a galvanic system contact.

As can be further seen in FIG. 1 to 3, the illustrated exemplary embodiment of the power module arrangement 1 comprises three power modules 2, 2A, 2B, 2C. In the illustrated exemplary embodiment of the power module arrangement 1, the three power modules 2, 2A, 2B, 2C each comprise a first circuit carrier (not shown in detail), on which at least two semiconductor switches (not shown in detail) are arranged. Here, at least one first semiconductor switch, which is also referred to as a high-side switch, is electrically looped between a first external contact surface 2.1A, which is connected to a first, or positive, external supply connection 32A, and a third external contact surface 2.1C, which is connected to the at least one external load connection 34. At least one second semiconductor switch, which is also referred to as a low-side switch, is electrically looped between a second external contact surface 2.1B, which is connected to a second, or negative, external supply connection 32B, and the third external contact surface 2.1C, which is connected to the at least one external load connection 34. The control connections of the at least two semiconductor switches are each electrically connected to at least one external contact element 2.2, which is arranged on a second circuit carrier and can be contacted with at least one control line of an external control contact device. The second circuit carrier is connected to the first circuit carrier via a soldered connection or sintered connection or welded connection or adhesive connection.

As can be further seen in FIG. 1 to 3, the individual power modules 2, 2A, 2B, 2C are each overmolded by a sheathing 3, which has an opening 5 in the region of the external contact surfaces 2.1, 2.1A, 2.1B, 2.1C so that the external contact surfaces 2.1, 2.1A, 2.1B, 2.1C can be contacted. In the region of the external contact elements 2.2, an exposure 7 is introduced into the sheathing 3 so that the contact elements 2.2 are exposed and can be contacted.

As can be seen in particular in FIG. 1 to 3, the individual power modules 2A, 2B, 2C each comprise two first external contact surfaces 2.1A, which are connected to the first, or positive, external supply connection 32A via a first connection interface 10A, a second external contact surface 2.1B, which is connected to the second, or negative, external supply connection 32A via the first connection interface 10A, and two third contact surfaces 2.1C, which are each connected to an external load connection 34 via a second connection interface 10B. Thus, the three power modules 2A, 2B, 2C each have a first connection interface 10A, which electrically connects the corresponding power module 2A, 2B, 2C to the first, or positive, supply connection 32A and the second supply connection 32B, and each have a second connection interface 10B, which electrically connects the corresponding power module 2A, 2B, 2C to the corresponding load connection 34. Here, the two third external contact surfaces 2.1C of a first power module 2A arranged at the top in the illustration are electrically connected to a load connection 34 designed as a first phase connection 34U, and provide a first phase current for an electrical machine. The two third external contact surfaces 2.1C of a second power module 2B arranged centrally in the illustration are electrically connected to a load connection 34 designed as a second phase connection 34V, and provide a second phase current for the electrical machine. The two third external contact surfaces 2.1C of a third power module 2C arranged at the bottom in the illustration are electrically connected to a load connection 34 designed as a third phase connection 34W, and provide a third phase current for the electrical machine.

In the illustrated exemplary embodiment of the power module arrangement 1, a capacitor assembly 30, which comprises a plurality of film capacitors (not shown), provides the first, or positive, supply connections 32A and the second, or negative, supply connections 32B for the three power modules 2, 2A, 2B, 2C, which are supported by a support element 36 made of plastic. The three phase connections 34U, 34V, 34W are each connected to a three-phase electric motor (not shown in detail). In addition, the three power modules 2, 2A, 2B, 2C are each thermally coupled to a cooling device 9 via a metal structure 4 arranged on the underside of the individual power modules 2, 2A, 2B, 2C, in order to dissipate heat loss caused by the individual power modules 2, 2A, 2B, 2C.

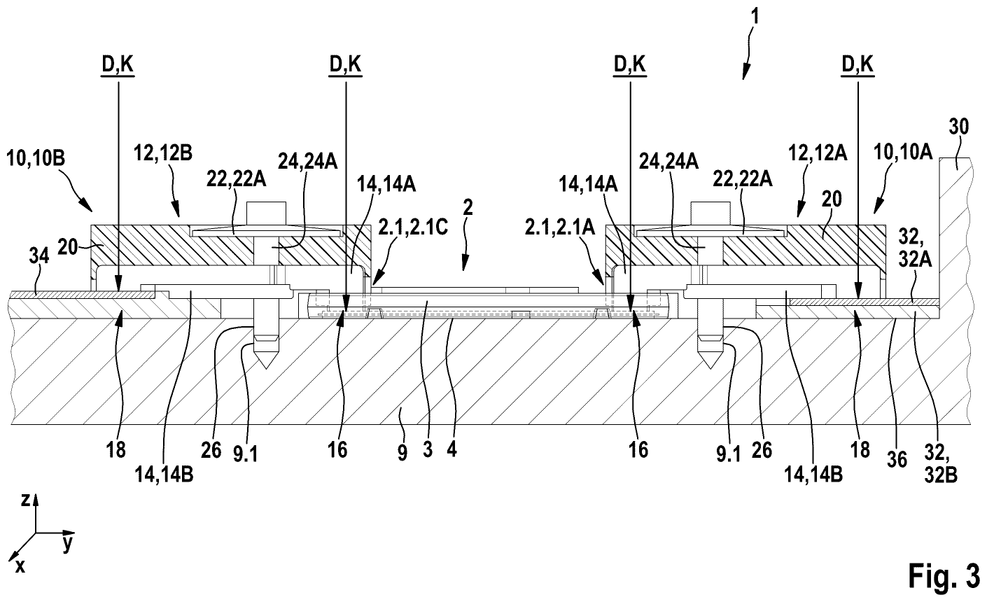

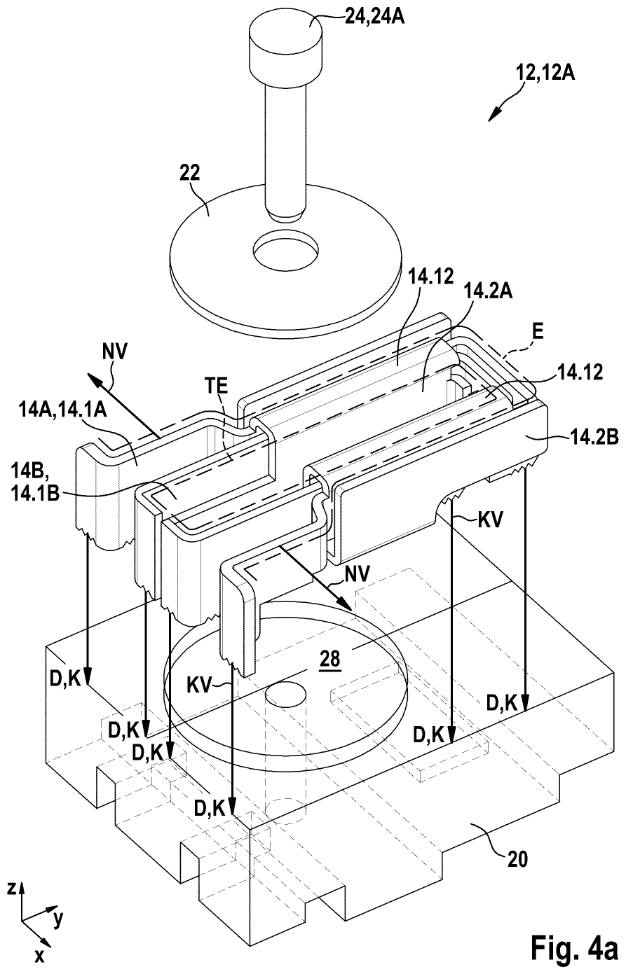

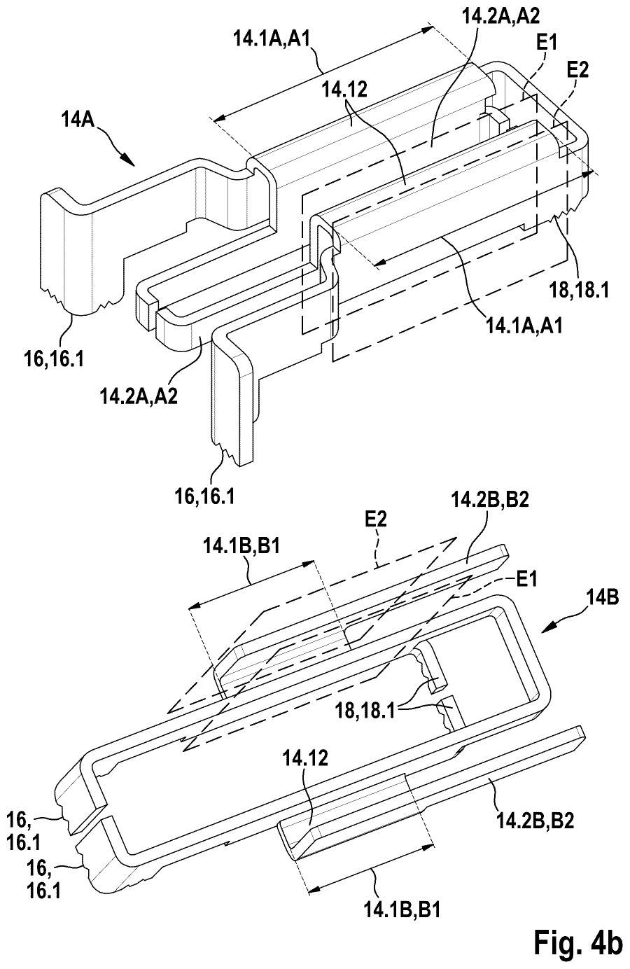

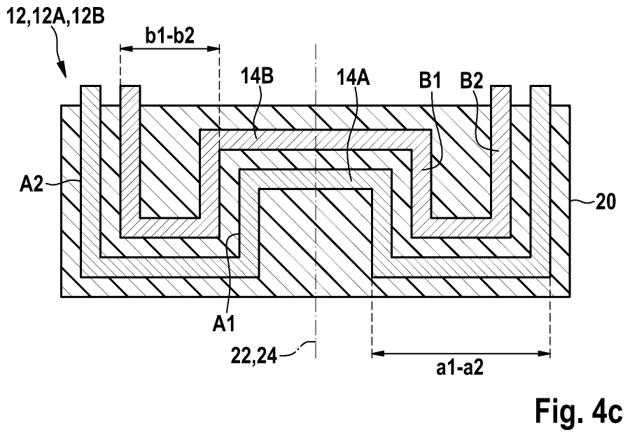

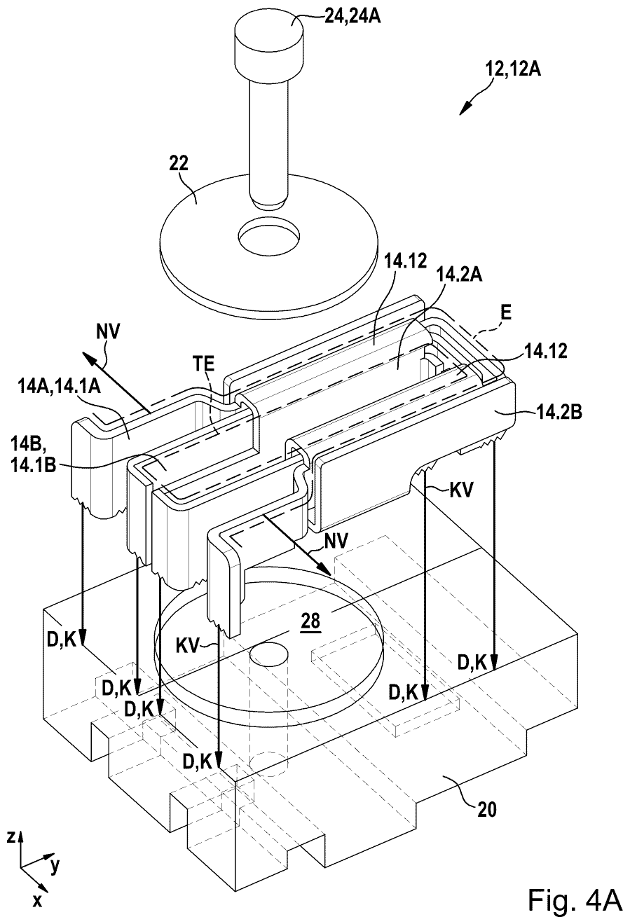

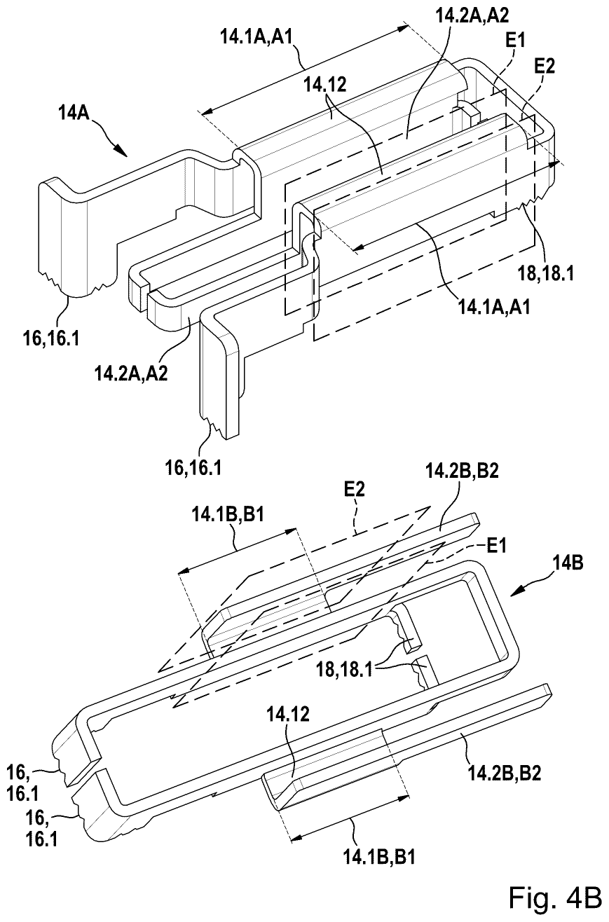

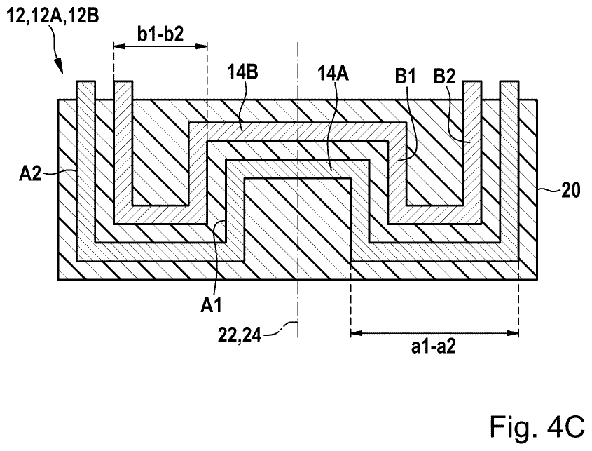

As can be further seen in FIG. 3 to 4C, the first connection interface 10A of one of the power modules 2, 2A, 2B, 2C in each case in the exemplary embodiment shown comprises a first external contact device 12A overmolded by the sheathing 20, which contact device electrically connects the two first external contact surfaces 2.1A of the corresponding power module 2, 2A, 2B, 2C to the first supply connection 32A and electrically connects the second external contact surface 2.1B of the corresponding power module 2, 2A, 2B, 2C to the second supply connection 32B. For this purpose, the first contact device 12A comprises at least two busbars 14A, 14B, each of which has at least a first contact region 16 and a second contact region 18.

As can be further seen in FIGS. 4A and 4B, the contact elements 16.1 of the first contact region 16 of the first busbar 14A are each designed as a row of sharp teeth 16.1A, which press the effected contact force K in the form of a pressure force D into the two first external contact surfaces 2.1A of the corresponding power module 2A, 2B, 2C. The contact element 18.1 of the second contact region 18 of the first busbar 14A is also designed as a row of sharp teeth 18.1A, which press the effected contact force K in the form of a pressure force D into the first, or positive, external supply connection 32A. The first contact device 12A also comprises a second busbar 14B, which each have a first contact region 16 and a second contact region 18. Here, the contact elements 16.1 of the first contact region 16 of the second busbar 14B are also designed as a row of sharp teeth 16.1A, which press the effected contact force K in the form of a pressure force D into the second external contact surface 2.1B of the corresponding power module 2A, 2B, 2C. The contact elements 18.1 of the second contact region 18 of the second busbar 14B are also designed as a row of sharp teeth 18.1A, which press the effected contact force K in the form of a pressure force D into the second, or negative, external supply connection 32B.

As can be further seen in FIG. 3 to 4C, the at least first and second busbars 14A, 14B of the first contact devices 12A are arranged in parallel with one another at a certain distance a in order to reduce parasitic inductances. The busbars 14A, 14B of the first contact device 12A are preferably designed as stamped and bent parts, but can also be laser-cut sheet metal bent parts, for example. One busbar 14A, 14B in each case has a continuous surface region 15 over an extension E from its first to its second contact region 16, 18, in which surface region the normal vector NV of each surface point is oriented perpendicularly to a force vector KV of the pressure force D. In the present exemplary embodiment, the continuous surface region 15 is realized, purely as an illustration, as a rectangular sheet metal strip running largely with a strip width b over the extension region E. Depending on the contacting situation, this can be adapted accordingly. Preferably, a remaining minimum surface span within the continuous surface region 15 is a multiple of the sheet thickness d, in particular more than 5 times, advantageously more than 10 times, preferably more than 15 times.

The first busbar 14A is guided along a U-shaped extension E. The second busbar 14B substantially follows an o-shaped extension E. The extension E of each busbar 14A, 14B may also be designed differently in order to be adapted to a specific application, for example with a substantially i-shaped extension. More than two busbars 12A, 12B may also be provided. The exemplary embodiment of the first contact device 12A shown here is adapted to the application within the described power module arrangement 1.

At least part or all of the entire rail portion 14.1A, 14.1B of one busbar 14A, 14B in each case has at least one laterally formed flange outlet 14.12, forming in each case a side rail portion 14.2A, 14.2B. This side rail portion is arranged in a different plane E1, E2 than the corresponding rail portion 14.1A, 14.1B of the corresponding busbar 14A, 14B. Furthermore, the side rail portions 14.2A, 14.2B of the first and second busbars 14A, 14B are arranged in parallel with one another, substantially overlapping one another. The flange outlet 14.12 is designed in particular as an angled portion, for example as a sheet metal bend. Purely as an illustration, the exemplary embodiment shows the busbars 14A, 14B with two bends in the respective flange outlet 14.12, such that two legs A1, A2, B1, B2, arranged in parallel with one another, of a cross section, which is then U-shaped, of the corresponding busbar 14A, 14B are formed in each case. In principle, it is possible that the opposite legs A1, A2, B1, B2 of each busbar 14A, 14B are also at an angle to one another, in particular in the manner of an opening V. Within the first contact device 12A, the U-shaped cross sections of the first and the second busbar 14A, 14B are arranged 180° opposite to one another. In a corresponding alternation, a leg A1, B1 of one of the busbars 14A, 14B engages between two corresponding legs B1, B2, A1, A2 of the other busbar 14A, 14B. Thus, the rail portions 14.1A, 14.1B and the side rail portions 14.2A, 14.2B of both busbars 14A, 14B are arranged in parallel with one another, substantially overlapping one another.

FIG. 4C additionally shows, in a highly schematic exemplary sectional view perpendicular to an extension E of the busbars 14A, 14B, another possibility of the engagement of the legs A1, A2, B1, B2. In this case, an arrangement of the two busbars 14A, 14B is selected in which their U-shaped cross sections are arranged in the same direction to one another. Furthermore, the two legs A1, A2, B1, B2 of one of the busbars 14A, 14B are at a greater distance a1-a2, b1-b2 from each other than the two legs A1, A2, B1, B2 of the other busbar 14A, 14B. Finally, the U-shaped cross section of the other busbar 14A, 14B is accommodated between the further protruding legs a1-a2, b1-b2 of the one busbar 14A, 14B.

As can be further seen in FIGS. 1 and 3, the second connection interface 10B in the exemplary embodiment shown comprises a further second external contact device 12B overmolded by the sheathing 20 and electrically connects the two third external contact surfaces 2.1C of the corresponding power module 2, 2A, 2B, 2C to the corresponding load connection 34. The second contact device 12B differs from the first contact device 12A only in that the extension E of each of the at least two contained busbars 14A, 14B, as well as the number and design of each of their first and second contact regions 16, 18, are correspondingly structurally adapted to the contacting of three third external contact surfaces 2.1C of the corresponding power module 2, 2A, 2B, 2C.

As can be further seen in particular in FIG. 3 to 4C, an elastic pressure element 22 is designed as a pressure disk 22A made of spring steel and is arranged in a recess 28 of the overmolding 20 of the corresponding contact device 12A, 12B. In the illustrated exemplary embodiment, the mechanical force application 24, which acts on and prestresses the elastic pressure element 22, is designed as a screw 24A. The screw 24A is screwed into a threaded bore 9.1, which is screwed into a base body of the cooling device 9.

In an alternative exemplary embodiment (not shown), the mechanical force application 24 is designed as a nut which is screwed onto a threaded shaft and acts on and prestresses the elastic pressure element 22.

1-15. (canceled)

16. A contact device for electrical contacting of at least two electrical functional elements of an electrical and/or electronic circuit and/or subcircuit within at least one connection interface, the contact device comprising:
at least a first busbar and a second busbar, which are arranged at a distance from one another in an electrically insulated manner, wherein each busbar of the first and the second busbars has at least a first and a second contact region, each of the first and second contact regions including at least one contact element, and the contact device is configured such that, when the functional elements are electrically contacted with, in each case, both of the first and the second busbars on the contact elements of different contact regions, a current path is formed in each case between the first and the second contact region within the first and the second busbar, wherein the electrical contacting of the contact element of at least one contact region with at least one contact surface of a functional element can be formed in the form of a force-loaded galvanic system contact in that the contact device has an arrangement which, in a contacting state of the contact device with at least one of the functional elements, effects a pressure force perpendicular to the contact surface as a contact force on the at least one contact element in at least one of the contact regions,
wherein the first and the second busbars are each formed from a plate-shaped base material with a plate thickness between two opposite outer surfaces, wherein the first and the second busbars each have rail portions arranged in parallel with one another over an extension between the first and the second contact region, wherein each respective rail portion of each of the first and second busbars has a laterally formed flange outlet, forming a side rail portion which is arranged in a different plane than a corresponding rail portion of the other of the first and second busbars, and wherein the side rail portions of the first and second busbars are arranged in parallel with one another, substantially overlapping one another.

17. The contact device according to claim 16, wherein each of the side rail portions of each of the first and second busbars is formed on the respective rail portion over at least a partial portion by at least one bend.

18. The contact device according to claim 17, wherein the each rail portion and each the side rail portion of each of the first and second busbars are arranged in parallel with one another or at an opening angle to one another, via two bends, in each case as legs of a U-shaped cross section of the first and second busbars.

19. The contact device according to claim 18, wherein the U-shaped cross sections of the first and the second busbar are arranged 180° opposite to one another, wherein at least one leg of one of the first and second busbars engages between two legs of the other of the first and second busbar.

20. The contact device according to claim 18, wherein the U-shaped cross sections of the first and the second busbar are arranged in the same direction to one another, wherein the legs of one of the first and second busbars are at a greater distance from one another than the legs of the other of the first and second busbars wherein the U-shaped cross section of the other of the first and second busbars is accommodated between further protruding legs of the one of the first and second busbars.

21. The contact device according to claim 16, wherein the rail portions and the side rail portions of both of the first and second busbars are arranged in parallel with one another, substantially overlapping one another.

22. The contact device according to claim 16, wherein each of the first and second busbars has a continuous surface region over an extension from its first contact region to its second contact region, in which surface region a normal vector f each surface point is oriented perpendicularly to a force vector of the pressure force.

23. The contact device according to claim 16, wherein the first and the second busbars are embedded in a common, electrically insulating sheathing, wherein the at least one contact element of the at least one first contact region and the at least one contact element of the at least one second contact region of each of the first and second busbars protrude from the sheathing.

24. The contact device according to claim 16, wherein the arrangement which effects the contact force includes at least one elastic pressure element, which is configured to be prestressed by a mechanical force application order to effect the contact force.

25. The contact device according to claim 16, wherein the at least one contact element of the at least one first contact region and/or the at least one contact element of the at least one second contact region are each configured a row of sharp teeth and are configured to be pressed into the at least one contact surface of the functional element by the contact force that can be effected.

26. A power module arrangement, comprising:
at least one power module includes a plurality of semiconductor switches and at least one external contact surface; and
at least one connection interface which includes at least one contact device for electrical contacting of at least two electrical functional elements of an electrical and/or electronic circuit and/or subcircuit within at least one connection interface, the contact device including:
at least a first busbar and a second busbar, which are arranged at a distance from one another in an electrically insulated manner, wherein each busbar of the first and the second busbars has at least a first and a second contact region, each of the first and second contact regions including at least one contact element, and the contact device is configured such that, when the functional elements are electrically contacted with, in each case, both of the first and the second busbars on the contact elements of different contact regions, a current path is formed in each case between the first and the second contact region within the first and the second busbar, wherein the electrical contacting of the contact element of at least one contact region with at least one contact surface of a functional element can be formed in the form of a force-loaded galvanic system contact in that the contact device has an arrangement which, in a contacting state of the contact device with at least one of the functional elements, effects a pressure force perpendicular to the contact surface as a contact force on the at least one contact element in at least one of the contact regions,
wherein the first and the second busbars are each formed from a plate-shaped base material with a plate thickness between two opposite outer surfaces, wherein the first and the second busbars each have rail portions arranged in parallel with one another over an extension between the first and the second contact region, wherein each respective rail portion of each of the first and second busbars has a laterally formed flange outlet, forming a side rail portion which is arranged in a different plane than a corresponding rail portion of the other of the first and second busbars, and wherein the side rail portions of the first and second busbars are arranged in parallel with one another, substantially overlapping one another
wherein the arrangement which effects the contact force includes at least one elastic pressure element, wherein the elastic pressure element is prestressed by a mechanical force application, whereby the contact force in the form of the pressure force is effected, with which at least one contact element of the first contact region of at least one of the first and second busbars is pressed against the at least one external contact surface, forming the galvanic system contact.

27. The power module arrangement according to claim 26, wherein a first connection interface of the at least one connection interface includes a contact device and is configured to electrically connect at least a first external contact surface of the at least one power module to a first supply connection and to electrically connect at least a second external contact surface of the at least one power module to a second supply connection.

28. The power module arrangement according to claim 27, wherein a second connection interface of the at least one connection interface includes a further contact device and is configured to electrically connect at least a third external contact surface of the at least one power module to a load connection.

29. The power module arrangement according to claim 26, wherein the at least one power module includes at least one circuit carrier, on which at least two semiconductor switches are arranged, wherein at least one first semiconductor switch of the semiconductor switches is electrically looped between a first external contact surface, which is connected to a first external supply connection, and a third external contact surface, which is connected to the at least one external load connection, and at least one second semiconductor switch is electrically looped between a second external contact surface, which is connected to a second external supply connection, and the third external contact surface, which is connected to the at least one external load connection.

30. The power module arrangement according to claim 26, wherein the at least one power module includes three power modules, wherein at least one third external contact surface of a first power module of the three power modules s electrically connected to a load connection configured as a first phase connection and provides a first phase current for an electrical machine, wherein at least one third external contact surface of a second power module of the three power modules is electrically connected to a load connection configured as a second phase connection and provides a second phase current for the electrical machine, and wherein at least one third external contact surface of a third power module of the three power modules is electrically connected to a load connection configured as a third phase connection and provides a third phase current for the electrical machine.
